(19) United States
(12) Patent Application Publication
(10) Pub. No.: US 2024/0290785 A1
(43) Pub. Date: Aug. 29, 2024

(54) Reducing Defects In a Polysilicon Overlaid Fin Structure

(71) Applicant: Texas Instruments Incorporated, Dallas, TX (US)

(72) Inventors: Abbas Ali, Plano, TX (US); Bhaskar Srinivasan, Allen, TX (US); John Shriner, Allen, TX (US); Edmond B. Benton, Prosper, TX (US)

(21) Appl. No.: 18/176,430

(22) Filed: Feb. 28, 2023

(51) Int. Cl. H01L 27/088; H01L 21/8234

(52) U.S. Cl. CPC H01L 27/0886; H01L 21/823431

(57) ABSTRACT

Forming an integrated circuit by first, forming a first fin and a second fin from a semiconductor layer, with an area between the first fin and the second fin, second, forming a dielectric layer covering at least a portion of the first fin, at least a portion of the second fin, and at least a portion of the area, and third, forming amorphous polysilicon covering a least a portion of the dielectric layer.

### CROSS-REFERENCE TO RELATED APPLICATION

Not applicable.

### FIELD

This disclosure relates to the field of semiconductor manufacturing, and more particularly, but not exclusively, to an integrated circuit (IC) manufactured with processes that form a fin device, such as a fin transistor.

### BACKGROUND

Metal oxide semiconductor (MOS) transistors, or field effect transistors (FET), typically include at least three regions in a semiconductor material, namely, a source, drain, and a body, for including a channel, between the source and drain. Historically, many MOSFETs were formed with these regions in the semiconductor material below a planar surface, whereby a current path through the body channel is generally oriented in the same direction, or plane, as the planar surface. More recently, transistors have been developed with the source and drain regions, at least in part, located in so-called fins, which are semiconductor protrusions extending from a generally planar semiconductor surface. These devices are sometimes referred to as fin transistors, or finFETs. Each fin is typically parallel to another fin(s), providing multiple surfaces protruding away from the planar semiconductor surface, and with a space between adjacent fins, for example defining a trench. A source (or drain) region in one fin can continue in the semiconductor material below the space next to that fin, and further continue to the source (or drain) region in the next adjacent fin, and so on, so that the source (or drain) region as a whole can span many fins. Similarly, the transistor gate, separated from the fin by a gate dielectric, may align with the contour of one or more of these multiple surfaces, and can continue across multiple fins. Accordingly, rather than a completely planar current path, the finFET current path, and total transistor size, can be realized in three dimensions and across multiple fins.

FinFETs can provide various advantages as well as complexities, as compared to planar devices. As benefits, for example, finFETs may realize any one or more of faster switching times, increased current density, and smaller areal footprints. As complexities, however, the three-dimensional fin structure raises various new considerations. As one example, the fin dimension is defined, in part, based on the trench dimensions between parallel fins. The trench dimension can include height and width, and typically trench formation does not yield an exact rectangular trench shape, so also of potential impact is any tilting in the trench sidewalls and rounding at corners, either at the trench top or bottom. These geometries present different considerations from traditional planar devices. Accordingly, this document provides examples that may improve on certain of the above concepts, as detailed below.

### SUMMARY

A method of forming an integrated circuit, including, first, forming a first fin and a second fin from a semiconductor layer, with an area between the first fin and the second fin; second, forming a dielectric layer covering at least a portion of the first fin, at least a portion of the second fin, and at least a portion of the area; and third, forming amorphous polysilicon covering a least a portion of the dielectric layer.

Other aspects are also described and claimed.

### BRIEF DESCRIPTION OF THE DRAWINGS

FIGS. 1A and 1B are respective perspective and cross-sectional views representing an IC first fabrication stage.

FIGS. 2A and 2B are respective perspective and cross-sectional views representing an IC second fabrication stage.

FIGS. 3A and 3B are respective perspective and cross-sectional views representing an IC third fabrication stage.

FIGS. 4A and 4B are respective perspective and cross-sectional views representing an IC fourth fabrication stage.

FIGS. 5A and 5B are perspective views, with FIG. 5B extended in the y-dimension relative to FIG. 5A, representing an IC fifth fabrication stage.

FIG. 6A is a perspective view of an alternative semiconductor structure 600, relative to FIG. 5B, that may result if deviating from an example formation of the FIGS. 4A/4B IC fourth fabrication stage.

FIG. 6B illustrates a cross-sectional view of the FIG. 6A alternative semiconductor structure 600, prior to the formation of the alternative gate conductor 602A.

FIG. 6C illustrates a cross-sectional view of the FIG. 6A alternative semiconductor structure 600, after the formation of the alternative gate conductor 602A.

FIG. 7 is a method 700 illustrating IC fabrication steps, including and in addition to the steps for forming the structures in FIGS. 1A through 5B.

### DETAILED DESCRIPTION

Examples are described with reference to the attached figures. The figures are provided to illustrate the examples and may not be drawn to scale. Reference to relative position, such as upper, lower, and the like are not absolute, but are for use in describing the drawings from the views shown. Several aspects are described with reference to example applications for illustration, in which like features correspond to like reference numbers. Numerous specific details, relationships, and methods are set forth to provide an understanding, but the scope is not necessarily limited by the illustrated ordering of acts or events, as some acts may occur in different orders and/or concurrently with other acts or events. Further, not all illustrated acts or events may be required to implement a methodology in accordance with one or more examples.

Various disclosed methods and devices of the present disclosure may be beneficially applied to ICs including fin transistors. Some such examples may be expected to reduce defects caused by seams in polycrystalline silicon (polysilicon) that fills a space between adjacent fins, or potentially in other trench structures. But no particular result is a requirement of the present invention unless explicitly recited in a particular claim.

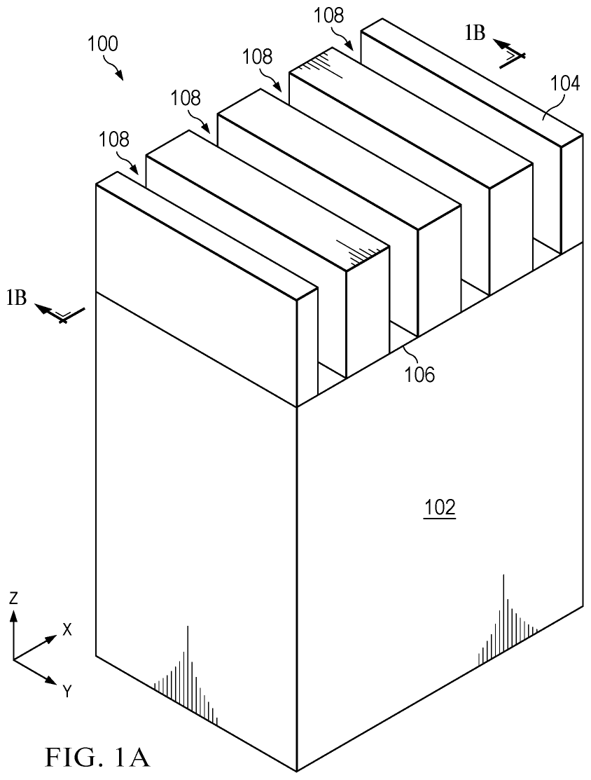

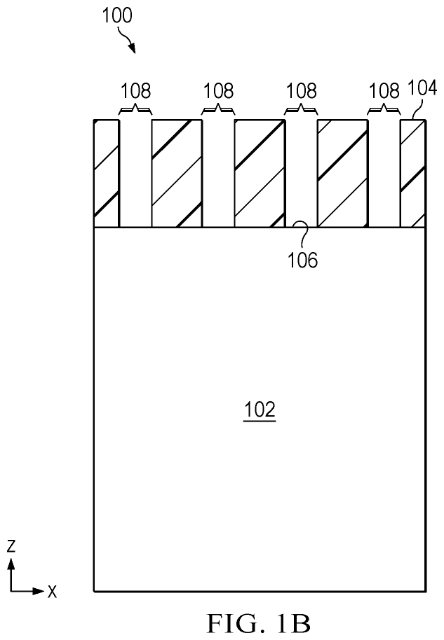

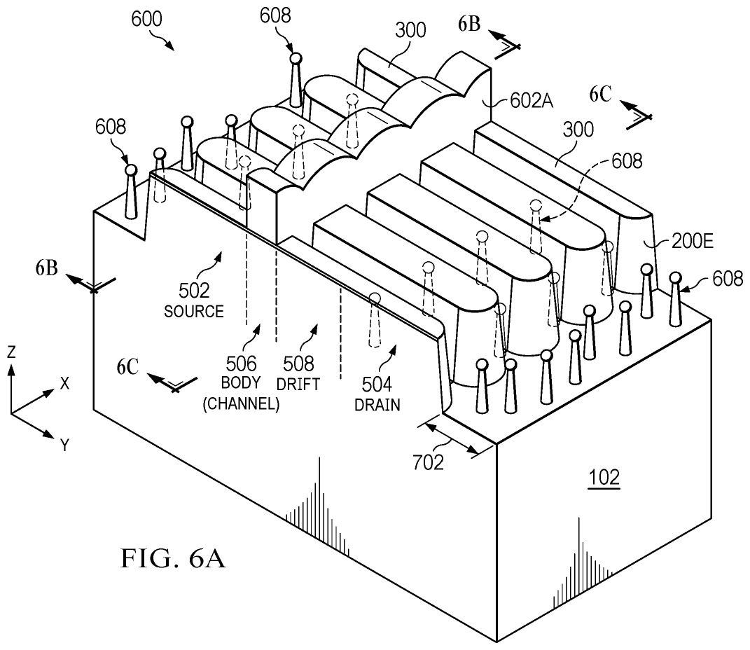

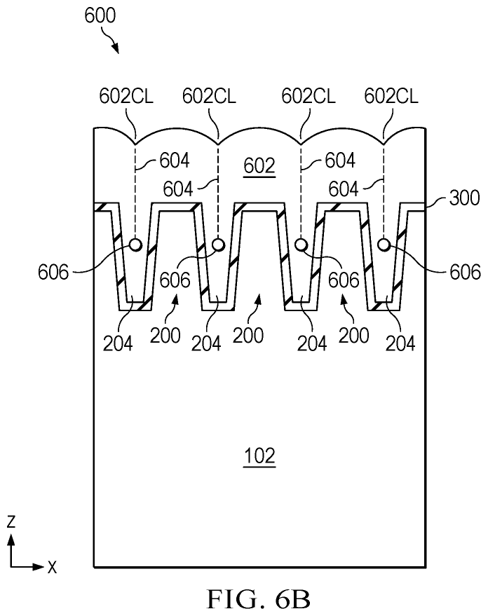

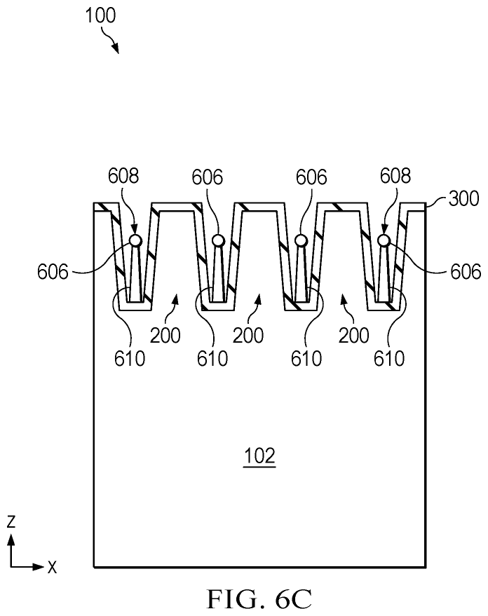

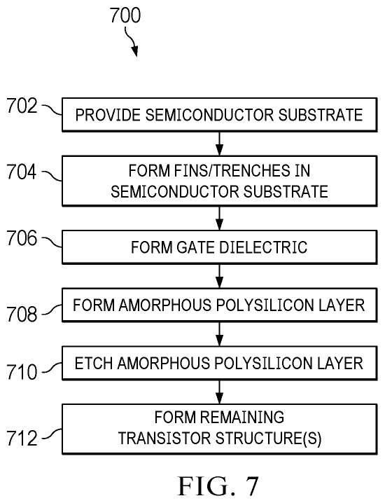

FIGS. 1A through 5B are various perspective or cross-sectional views representing successive fabrication stages and resultant structures of a semiconductor structure 100 in an IC. For sake of FIG. 1A and later figures, x-y-z coordinate directions are also illustrated, with a semiconductor substrate 102 generally along the x-y plane. The directional references are for purposes of relative placement, but such terms are not intended to be restrictive as the device may be rotated in space and thereby change absolute, but not relative, references. FIG. 7 is a method 700, in flow chart form, that summarizes steps of the fabrication stages shown in the views of FIGS. 1A through 5B. As detailed later, FIG. 6A is a perspective view, and FIGS. 6B and 6C are cross-sectional views, of contrasting structural features, that may be undesirably incurred if deviating from certain described example implementation steps.

In the respective perspective and cross-sectional views of FIGS. 1A and 1B, (and method step 702) a semiconductor structure 100 is provided at an early manufacturing stage. The semiconductor structure 100 includes a semiconductor substrate 102, for example as part of a silicon wafer. Such a wafer typically includes multiple locations, each corresponding to a same or different IC on the wafer, so the illustration of FIGS. 1A and 1B (and later figures) can be repeated in each wafer IC location. The wafer typically provides either a p-type or n-type semiconductor, and the semiconductor substrate 102 can represent a portion of the bulk wafer or a region (e.g., a well, or a buried or epitaxial layer) formed in connection with the wafer. As detailed in the remaining figures, a finFET transistor is ultimately formed in connection with the semiconductor substrate 102, and that device is represented only by the general area shown in FIGS. 1A and 1B, where other devices may also be formed, concurrently or at separate times, in other locations of the semiconductor substrate 102. In connection with forming the finFET transistor, a first mask structure 104 is positioned relative to an upper surface 106 of the semiconductor substrate 102, where the upper surface 106 may be a planar surface. The upper surface 106 may be of the same material and the same monolithic structure of the semiconductor substrate 102, or may be an additional layer. For example, prior to locating the first mask structure 104, additional steps may be provided, such as forming an epitaxial layer, such as monocrystalline silicon, on top of the semiconductor substrate 102 (or separated from the semiconductor substrate 102 by another layer, for example forming a hard mask to a subsequent step or steps). Other additional transistor-related steps may be included, for example forming a reduced surface field (RESURF) layer (e.g., p-type) and/or a drift region (e.g., n-type) and or a buried layer (e.g., also n-type), which are not otherwise shown, relative to the upper surface 106. The first mask structure 104 may be a photoresist mask, or alternatively a hard mask. The first mask structure 104 includes one or more apertures 108, where four such apertures 108 are shown for sake of illustration, and through which an etch may be performed.

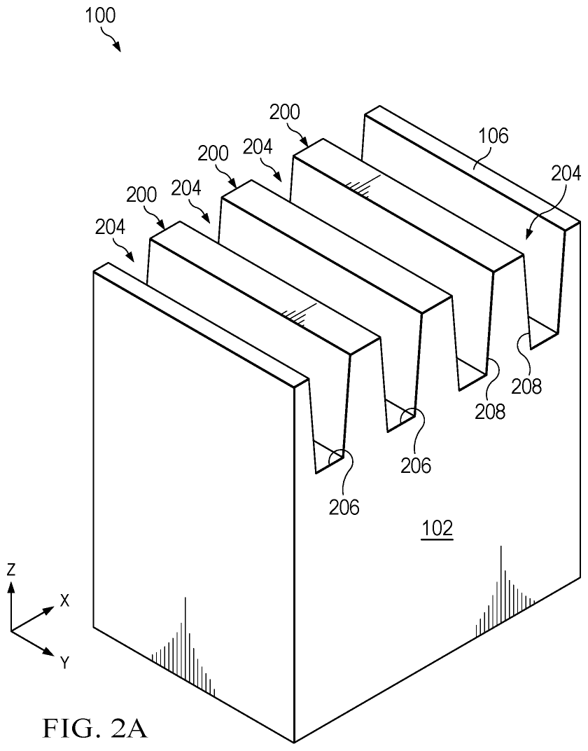

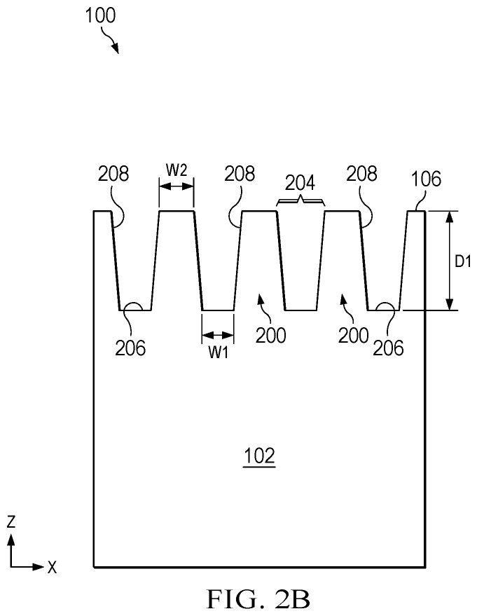

In the respective perspective and cross-sectional views of FIGS. 2A and 2B (and FIG. 7 method step 704), a plurality of fins 200 are formed protruding from the upper surface 106. In the example, the fins 200 are formed by an etch through the apertures 108 in the FIGS. 1A and 1B mask structure 104, into the upper surface 106, forming respective trenches 204 corresponding to each of the apertures 108. Each of the trenches 204 has a bottom surface 206, at a depth DI between the bottom surface 206 and the upper surface 106, where DI can range from 0.400 μm to 6.00 μm. Each of the trenches 204 also has opposing sidewalls 208 between the bottom surface 206 and the upper surface 106, where the sidewalls 208 also form counterpart sidewalls to adjacent ones of the fins 200. The opposing sidewalls 208 are shown to have an outward tilt from the bottom surface 206 by way of example, as is also possible given contemporary trench formation techniques, for example as part of photolithographic processes. Accordingly, a width W1 of each of the trenches 204 is smaller from the bottom surface 206 upward, and can range from 0.150 μm to 1.500 μm, for example with W1=0.210 μm at the bottom surface 206 and a top width of 0.260 μm. Various of the teachings herein may apply to much wider trenches, particularly if the trenches are deeper. Additionally, the figures illustrate the intersection of each of the sidewalls 208 to a corresponding surface (either the upper surface 106 or the bottom surface 206) to form an angle, but in practice the relationship may be more curved, particularly at the outward edges of the bottom surfaces 206. Spacing of the vertical center of each of the trenches 204 also creates a width W2 for the top of each of the fins 200, where the width W2 and can range from 0.150 μm to 1.500 μm, such that various aspects herein may apply to various different pitches.

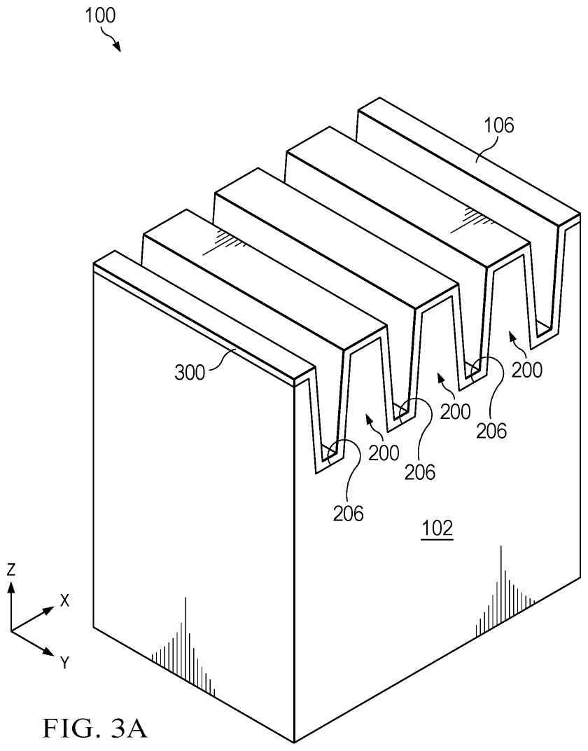

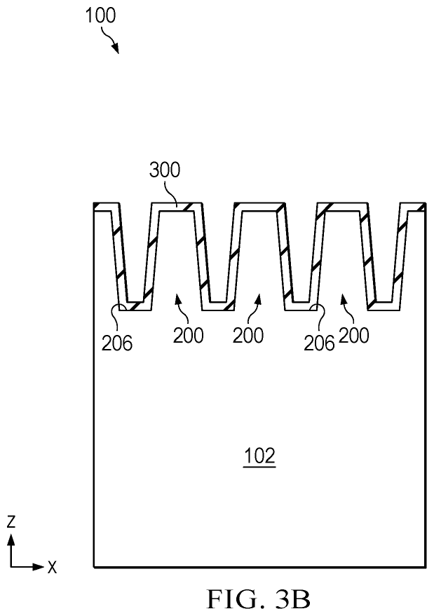

In the respective perspective and cross-sectional views of FIGS. 3A and 3B (and FIG. 7 method step 706), a dielectric layer 300 is formed over exposed surfaces of the semiconductor structure 100. In the illustrated example, the dielectric layer 300 may be thermally grown, forming a uniform thickness of silicon dioxide in a range from 0.005 μm to 1.000 μm. Generally, the dielectric layer 300 can be thicker for relatively deeper trenches. Further, the dielectric layer 300 may be one of various forms of SiO2, for example as tetraethoxysilane or tetraethyl orthosilicate (TEOS), high density plasma (HDP) oxide, or still others. Accordingly, the dielectric layer 300 forms along the upper surface 106, and also within the trenches 204, thereby aligning along the sidewalls 208 and the bottom surfaces 206. Also in connection with FIGS. 3A and 3B (or later as shown in FIG. 7 method step 712), but not expressly shown in FIGS. 3A and 3B, additional transistor features may be formed. For example, an additional mask or masks may be located in an appropriate position(s) to form a double diffused well (DWELL) through the exposed dielectric and into the semiconductor material beneath it. The DWELL formation may be, for example, by plasma doping (PLAD) with p-type (e.g., boron) and n-type (e.g., arsenic) dopants.

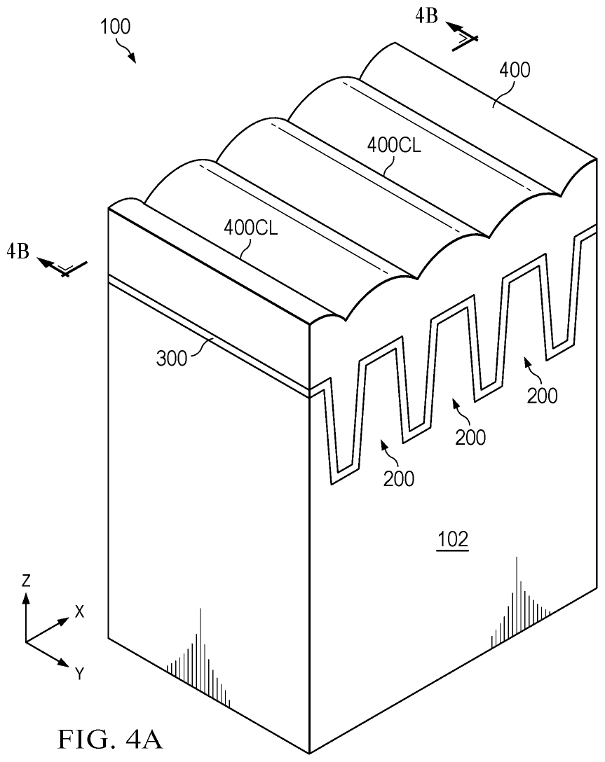

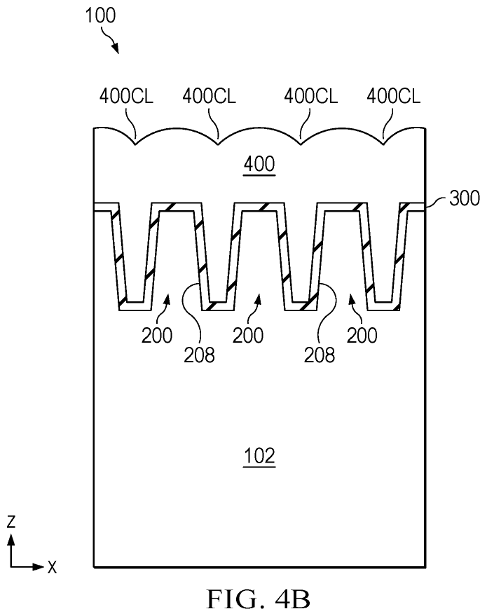

In the perspective view of FIG. 4A, and cross-sectional views of FIGS. 4B (and FIG. 7 method step 708), a polysilicon layer 400 is formed over exposed surfaces of dielectric, thereby covering the dielectric layer 300. In the illustrated example, the polysilicon layer 400 is deposited, for example using chemical vapor deposition (CVD), or low pressure chemical vapor deposition (LPCVD), at a temperature of 570° C. or less, for example at a temperature from 420° C. to 570° C. In an example, the lower temperature growth results in a material for the polysilicon layer 400 with no observable crystalline or grain structure, that is, tending toward or creating amorphous silicon, although at slightly higher temperatures some small grain and/or grain boundary detection is possible. In some examples, the deposition is at a temperature from 520° C. to 550° C., as temperatures greater than 550° C. may result in polysilicon with larger grain sizes, and temperatures below 520° C. may cause a very (and undesirably) slow growth of the material, particularly for thicker films. Further, the surface roughness of the polysilicon layer 400 is relatively low, for example at 5 nm or less, and in some instances at 2 nm or lower. Additionally, such material attributes are relatively uniform across an entire wafer that may include numerous wafer IC locations, each including at least one instantiation of the semiconductor structure 100. Lastly, for later reference, note in FIGS. 4A (and 4B) that “bread-loafing” occurs when the polysilicon layer 400 comes together, for example at center locations 400CL that are generally centered, in the x-dimension, between the sidewalls 208 of the trenches 204 (between the fins 200). The bread-loafing may occur from the conformal formation of the polysilicon layer 400 as it forms along various surfaces, including the sidewalls and bottom of the trenches 204 and develops a non-planar upper surface atop the semiconductor structure 100.

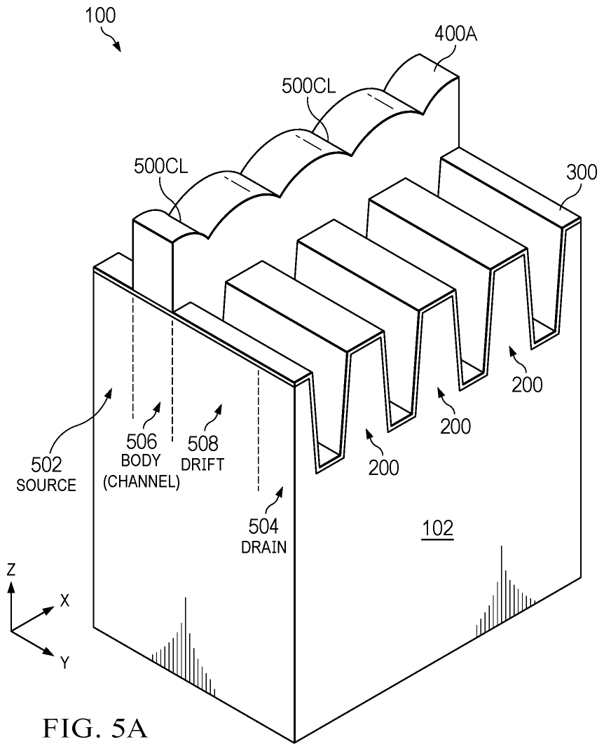

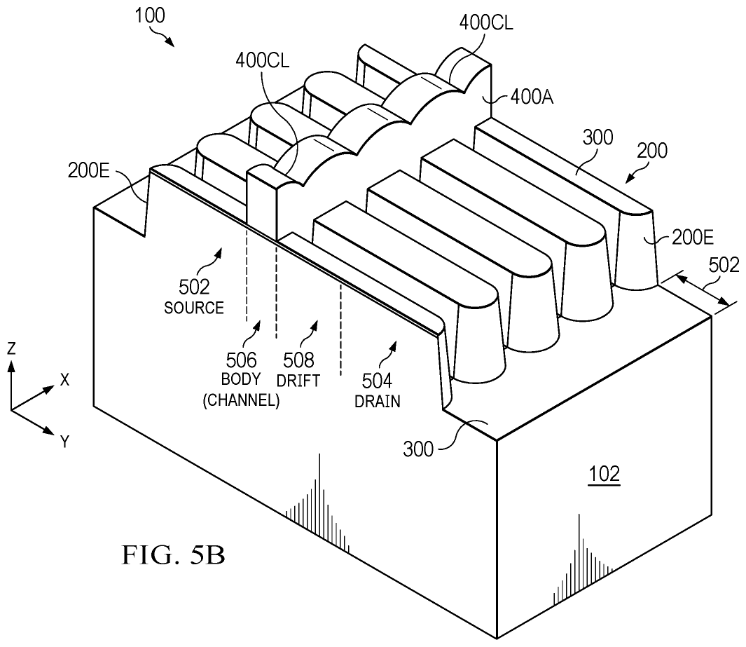

FIGS. 5A and 5B are perspective views, representing an additional fabrication stage (as also shown in FIG. 7 method step 710). FIG. 5A illustrates the semiconductor structure 100 in the same cutaway view as FIG. 4A, and for further illustration and elaboration, FIG. 5B illustrates the semiconductor structure 100 farther along the y-dimension, so as to illustrate the ends 200E of the fins 200 and also a field area 502, which is covered by the dielectric layer 300 and may be planar, and aligned with the x-y plane extending from the trench bottom surfaces 206 (see FIG. 2A). In the perspective and cross-sectional views of FIGS. 4A and 4B, a mask (not shown) is positioned relative to the polysilicon layer 400, and the polysilicon layer 400 is etched to form one or more transistor-related conductors. The etch may be at least partially isotropic and is desirably selective—for example highly selective, such as >1000:1—to polysilicon (highly selective of polysilicon to oxide), thereby removing the FIGS. 4A-4B polysilicon in unmasked areas, down to the dielectric layer 300 below it, that is, either on top of the fins 200 or within the trenches 204. Notably, and as introduced above, because the step 708 forms a material for the polysilicon layer 400 that may be amorphous or having some small grain attribute, it is less likely to include seam defects, paths, and/or voids, which could otherwise present small amounts of oxide to form within the polysilicon layer 400, for example at or below (in the z-dimension) the center locations 400CL and as detailed later. Since such defects are reduced or potentially eliminated, the FIGS. 5A and 5B etch provides a resultant structure(s) less prone to such defects. In the illustrated example, the etch-resultant structure (conductor(s)) provides a gate conductor 400A, although in some devices an additional conductor (e.g., a separate field plate conductor) may be aligned over differing portions of the fins, for example displaced from the gate conductor 400A in the y-dimension. In an example and in the x-dimension traversing over plural ones of the fins 200, the gate conductor 400A is in a range from 50 nm to 300 nm wide in the y-dimension (not necessarily shown to scale in the Figures). Accordingly, the gate conductor 400A may receive a bias from a contact (not shown) and apply that bias relative to the tops and sidewalls 208 of the fins 200, and the bottom surface 206 of the trenches 204, thereby including a channel in the semiconductor material near the surface in each of those areas. The FIGS. 5A and 5B (and step 710) etch also may be followed by planarization, although FIGS. 5A and 5B do not illustrate a planarized upper surface for the gate conductor 400A.

FIG. 6A illustrates an alternative semiconductor structure 600 in the same perspective view, and including the same features as the FIGS. 5A-5B semiconductor structure 100. For contrast, however, the alternative semiconductor structure 600 illustrates an alternative gate conductor 602A formed from an alternative polysilicon layer 602, which is formed at higher temperatures than those described above for the polysilicon layer 400. For example, the alternative semiconductor structure 600 may result if typical transistor gate formation processes are used, which are known to deposit polysilicon at higher temperature, such as at 600° C. or higher. Such an example is further described below, in connection with FIGS. 6B and 6C.

FIG. 6B illustrates a cross-sectional view of the FIG. 6A alternative semiconductor structure 600, prior to the formation of the alternative gate conductor 602A. In FIG. 6B, a standard (higher temperature) transistor gate process forms the alternative polysilicon layer 602, which conformally fills the trenches 204 (above the dielectric layer 300) between the fins 200. Further, a bread-loafing shape of the conformal alternative polysilicon layer 602 defines a center line 602CL above each trench 204. A seam (or other path or void) 604 also may form in the alternative polysilicon layer 602, in the z-dimension beneath each center line 602CL. The disclosure recognizes that the seam 604, particularly for larger crystal or grain size polysilicon, provides a path along which oxygen may pass into the alternative polysilicon layer 602, e.g. by grain boundary diffusion. The oxygen may then form an oxide structure 606 at some point or points along the seam 602, for example at the extreme end of the seam in the positions shown by each oxide structure 606. For example, it may be possible that such oxygen occurs during the formation of the polysilicon layer 600 (e.g., liberation of oxide from the dielectric layer 300 during polysilicon formation) or from ambient oxygen at a later time. In any event, the oxide structures 606 pose a problem during a subsequent etch to form the FIG. 6A alternative gate conductor 602A, as described below.

FIG. 6C illustrates a cross-sectional view of the FIG. 6A alternative semiconductor structure 600, after the formation of the FIG. 6A alternative gate conductor 602A. Note, as indicated in FIG. 6A, that the FIG. 6C cross-section is displaced in the y-dimension away from the FIG. 6A alternative gate conductor 602A, so that conductor 602A is not shown in FIG. 6C. In any event, when a highly-polysilicon-selective etch is applied to the FIG. 6B alternative polysilicon layer 602, the polysilicon is generally removed, but each oxide structure 606 blocks the area beneath it, in the z-dimension from being so etched. As a result, in FIG. 6C, and also as now appreciated in FIG. 6A, an unpredictable number of additional pillar structures 608 are formed. The pillar structures 608 may be formed in any one or more of the field area 502, between the fins 200, or even within the remaining polysilicon (as shown in dashed outline in FIG. 6A) that is left from the formation of the gate conductor 602A. Each of the pillar structures 608 may include a portion 610 of the previously-positioned polysilicon layer 602 that was unsuccessfully etched by etch intended to form the gate conductor 602A, and atop the portion 610 is the oxide structure 606, which may or may not be partially reduced by the etch, for example with a partial reduction occurring if that etch is less than infinitely selective to polysilicon versus oxide. In all events, the existence of the FIGS. 6A and 6C pillar structures 608 is undesirable, for example due to the possibility of causing defects in subsequent material depositions that may compromise device reliability. As shown in FIGS. 5A and 5B, however, an example is provided that avoids the FIGS. 6A and 6C drawbacks, for example with small grain or amorphous polysilicon that inhibits the passage of oxygen in areas of the bread-loafing. Further, such a result is achieved without having to reduce the polysilicon:oxide etch selectivity, which could instead undesirably remove portions of the polysilicon fins 200.

Completing FIG. 7, but without corresponding cross-sectional views, additional steps in manufacturing the semiconductor structure 100 are contemplated. For example, in a step 712, portions of which may have been performed earlier in the method 700, one or more additional semiconductor features are formed on or in a layer(s) of the semiconductor substrate 102 and including the fins 200, with like copies of each feature formed into each respective IC on the semiconductor wafer that includes the semiconductor substrate 102. The step 712 of forming the one or more additional semiconductor features may include almost any process used to form any feature. For example, the step 712 might include additional formation of DWELL structure, formation of sidewall spacers, for instance relative to the gate conductor 600A, implants, silicides, and contacts, so that ultimately the semiconductor structure 102 includes (referring to FIG. 5A) a source region 502, a drain region 504, a body region 506 (in which a channel can be induced) at least in one dimension between the source region 502 and the drain region 504, and optionally a drift region 508, also between the source region 502 and the drain region 504. The step 712 also may include other process steps, or a collection of different process steps, so that eventually all features for functional operation of the semiconductor structure 100 are complete.

Various disclosed methods and devices of the present disclosure may be beneficially applied to ICs, for example with respect to an IC that includes a fin device, such as a fin transistor. Such examples provide various benefits, some of which are described above and including still others. Examples are formed using a process that forms trenches between the fins, a dielectric along at least a portion of the fin/trench sidewalls, and a small grain (e.g., amorphous) polysilicon along the dielectric. In a subsequent etch more selective to the small grain polysilicon versus the dielectric, fewer defects may be realized. Other examples are contemplated, where an IC feature has a geometry that presents a seam/void when polysilicon is formed over a dielectric along that feature, and with a subsequent etch of the formed polysilicon.

What is claimed is:

1. A method of forming an integrated circuit, comprising:
first, forming a first fin and a second fin from a semiconductor layer, with an area between the first fin and the second fin;
second, forming a dielectric layer covering at least a portion of the first fin, at least a portion of the second fin, and at least a portion of the area; and
third, forming amorphous polysilicon covering a least a portion of the dielectric layer.

2. The method of claim 1 wherein the area between the first fin and the second fin is a trench.

3. The method of claim 2:
wherein the at least a portion of the first fin includes a sidewall of the first fin; and
wherein the at least a portion of the second fin includes a sidewall of the second fin.

4. The method of claim 3 wherein the at least a portion of the area includes a bottom surface of the trench.

5. The method of claim 4 wherein the third step includes forming the amorphous polysilicon covering the dielectric layer in the trench in the bottom of the trench.

6. The method of claim 5 and further including etching the amorphous polysilicon covering the dielectric layer in the trench in the bottom of the trench.

7. The method of claim 6 wherein the etching comprises etching with an infinite selectivity of the amorphous polysilicon relative to a material of the dielectric layer.

8. The method of claim 7 wherein the material includes oxide.

9. The method of claim 2 wherein the trench has a depth distance from 0.400 μm to 6.00 μm.

10. The method of claim 2 wherein the trench has a width distance from 0.150 μm to 1.500 μm.

11. The method of claim 1 wherein the step of forming amorphous polysilicon includes depositing the polysilicon at a temperature of 570° C. or less.

12. The method of claim 1 wherein the step of forming amorphous polysilicon includes depositing the polysilicon at a temperature in a range from 520° C. to 570° C.

13. The method of claim 1 wherein the step of forming amorphous polysilicon includes depositing the polysilicon at a temperature in a range from 520° C. to 550° C.

14. The method of claim 1 and further including forming a gate conductor from the amorphous polysilicon.

15. The method of claim 14 and further including forming a source region and a drain region in the first fin, the second fin, and the area.

16. The method of claim 15 and further including forming a drift region in the first fin, the second fin, and the area.

17. A method of forming an integrated circuit, comprising:
first, forming a trench in a semiconductor layer, the trench including a first and second sidewall and a bottom surface between the first and second sidewall;
second, forming a dielectric layer covering at least a portion of the first sidewall, the second sidewall, and the bottom surface;
third, forming polysilicon covering the dielectric layer, wherein the third step forms a bread-loafing shape in the polysilicon and a polysilicon grain structure that inhibits passage of oxygen into the polysilicon at a location of the bread-loafing shape.

18. The method of claim 17 wherein the step of forming polysilicon includes forming amorphous polysilicon.

19. The method of claim 17 and further including etching the polysilicon covering, and thereby exposing, the dielectric layer in the trench.

20. An integrated circuit comprising:
a semiconductor layer;
a first fin and a second fin extending from the semiconductor layer, with a trench between the first fin and the second fin;
a gate dielectric layer covering at least a portion of the first fin, at least a portion of the second fin, and at least a portion of the trench; and
an amorphous polysilicon gate covering a least a portion of the gate dielectric layer.
